(19) United States
(12) Patent Application Publication
(10) Pub. No.: US 2026/0229865 A1
(43) Pub. Date: Aug. 6, 2026

(54) BUSBAR ASSEMBLY

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: HSIU-YUAN HSU, New Taipei (TW); YAO-CHI HUANG, New Taipei (TW); WEN HE, Shenzhen (CN); MIN-SI WU, New Taipei (TW)

(21) Appl. No.: 19/459,358

(22) Filed: Jan. 26, 2026

(30) Foreign Application Priority Data
Jan. 24, 2025 (CN) 202510120942.1

(51) Int. Cl. H02G 5/10

(52) U.S. Cl. CPC H02G 5/10

(57) ABSTRACT

A busbar assembly includes a power busbar and a ground return busbar electrically isolated from the power busbar. The busbar assembly includes a thermal conduit disposed between the power busbar and the ground return busbar. The thermal conduit extends along the power busbar and the ground return busbar and is configured to allow liquid to flow through it to dissipate heat from the power busbar and the ground return busbar. A single thermal conduit is shared between the power busbar and the ground return busbar, allowing the cross-sectional size of the thermal conduit to be increased. This configuration effectively reduces fluid flow resistance, thereby improving heat dissipation efficiency. Additionally, the use of a single thermal conduit reduces manufacturing and assembly costs.

### BACKGROUND OF THE INVENTION

### Field of the Invention

The present invention relates to a busbar assembly, and more particularly to a busbar assembly with reliable heat dissipation.

### Description of Related Arts

U.S. Patent No. 12,178,019 discloses a busbar assembly comprising a power busbar, a ground return busbar, a first thermal conduit disposed on the power busbar for dissipating heat from the power busbar, and a second thermal conduit disposed on the ground return busbar for dissipating heat from the ground return busbar. However, the approach of using two separate thermal conduits to dissipate heat from the power busbar and the ground return busbar respectively results in limited cross-sectional areas for each thermal conduit, which increases the fluid resistance within the thermal conduits and hinders the circulation of liquid. Consequently, the thermal conduits are unable to reliably dissipate heat from the busbar assembly. Additionally, providing separate thermal conduits for the power busbar and the ground return busbar increases manufacturing and assembly costs.

### SUMMARY OF THE INVENTION

A busbar assembly configured to mate with an electrical component includes a power busbar, and a ground return busbar electrically isolated from the power busbar. The busbar assembly includes a thermal conduit disposed between the power busbar and the ground return busbar. The thermal conduit extends along the power busbar and the ground return busbar and is configured to allow liquid to flow through it to dissipate heat from the power busbar and the ground return busbar.

### BRIEF DESCRIPTION OF DRAWINGS

FIG. 1 shows a perspective view of a busbar assembly according to the present disclosure;

FIG. 2 shows an exploded perspective view of the busbar assembly according to the present disclosure;

FIG. 3 shows an exploded perspective view of the busbar assembly from another angle; and

FIG. 4 is a top view of the busbar assembly according to the present disclosure.

### DETAILED DESCRIPTION OF THE DRAWINGS

Reference will now be made in detail to the preferred embodiments of the present invention.

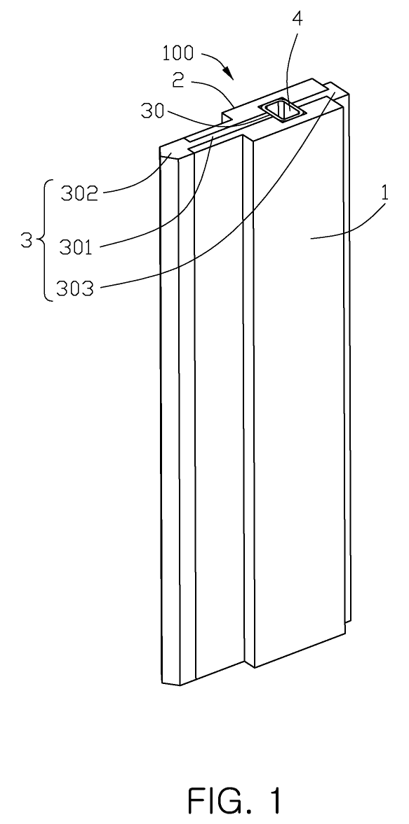

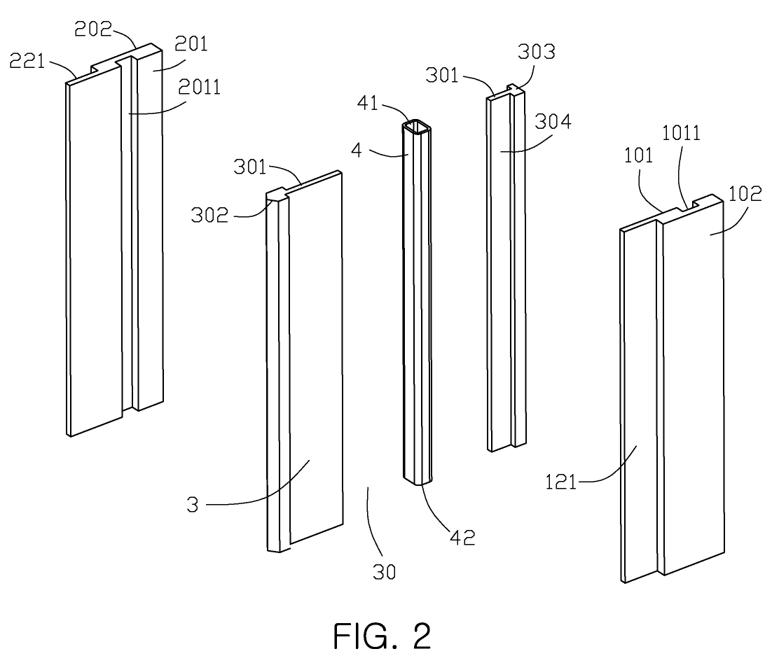

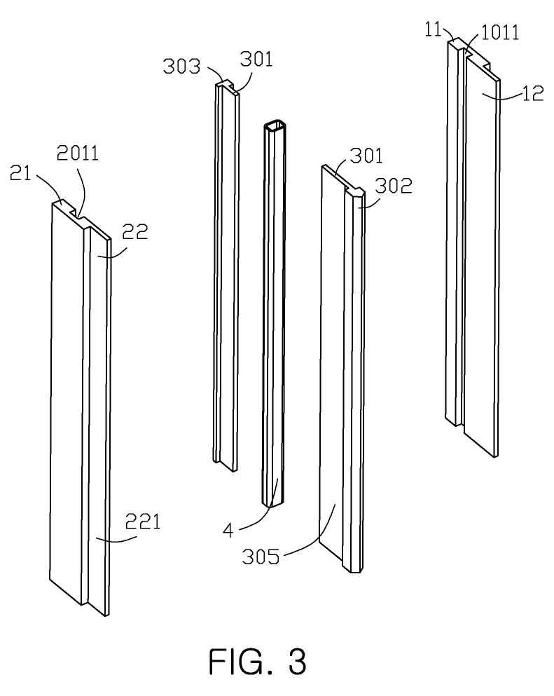

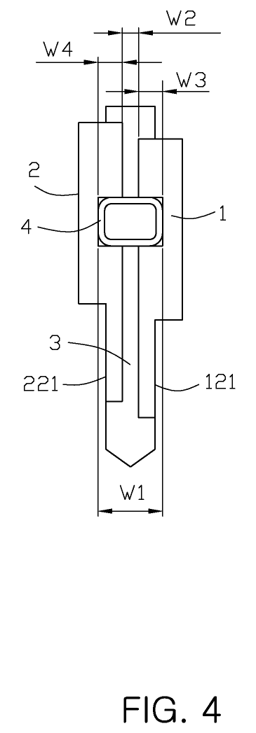

Referring to FIGS. 1-4 illustrating a busbar assembly 100 of an embodiment of this present invention, the busbar assembly 100 is used for supplying power to one or more of electrical components (not shown). The busbar assembly 100 includes a power busbar 1, a ground return busbar 2 electrically isolated from the power busbar 1, an isolator panel 3, and a thermal conduit 4.

The power busbar 1 and the ground return busbar 2 are elongated plate members extending in a vertical direction. The isolator panel 3 is disposed between the power busbar 1 and the ground return busbar 2 and extends along the entire height of the power busbar 1 and the ground return busbar 2 in the vertical direction, thereby electrically isolating the power busbar 1 from the ground return busbar 2. The power busbar 1 and the ground return busbar 2, together with the isolator panel 3, form a busbar element for supplying power to the electrical component (not shown). The thermal conduit 4 is disposed between the power busbar 1 and the ground return busbar 2 and extends along the power busbar 1 and the ground return busbar 2. The thermal conduit 4 allows liquid coolant to flow therethrough to dissipate heat from the power busbar 1 and the ground return busbar 2. In some embodiments, the isolator panel 3 is sandwiched between and contacts the power busbar 1 and the ground return busbar 2. However, the busbar assembly 100 may have other structures in alternative embodiments, such as having the power and ground return busbars 1, 2 separate from each other, such as spaced apart by an air gap.

The power busbar 1 is a metal plate having an inner surface 101 and an outer surface 102. The inner surface 101 faces the isolator panel 3. The ground return busbar 2 is a metal plate having an inner surface 201 and an outer surface 202. The inner surface 201 faces the isolator panel 3. The two sides of the thermal conduit 4 are electrically isolated from the power busbar 1 and the ground return busbar 2, respectively. Specifically, the thermal conduit 4 is externally provided with a thermally electrically insulating layer to electrically isolate the thermal conduit 4 from the power busbar 1 and the ground return busbar 2.

The isolator panel 3 has a recess 30, which accommodates the thermal conduit 4 so that the two sides of the thermal conduit 4 can respectively abut against the inner surface 101 of the power busbar 1 and the inner surface 201 of the ground return busbar 2. The inner surface 101 of the power busbar 1 is recessed to form a first busbar channel 1011, and the inner surface 201 of the ground return busbar 2 is recessed to form a second busbar channel 2011. The two sides of the thermal conduit 4 are respectively accommodated in the first busbar channel 1011 and the second busbar channel 2011.

Specifically, the power busbar 1 has a thicker rear portion 11 and a thinner front portion 12, while the ground return busbar 2 has a thicker rear portion 21 and a thinner front portion 22. The rear portion 11 of the power busbar 1 is disposed opposite the rear portion 21 of the ground return busbar 2, and the front portion 12 of the power busbar 1 is disposed opposite the front portion 22 of the ground return busbar 2. The outer side of the front portion 12 of the power busbar 1 forms a mating interface 121 that mates with the electrical components (not shown) to provide a power supply path to the electrical components (not shown). The outer side of the front portion 22 of the ground return busbar 2 forms a mating interface 221 that mates with the electrical components (not shown) to provide a power return path to the electrical components (not shown). The isolator panel 3 includes a substrate 301 sandwiched between the power busbar 1 and the ground return busbar 2, a front protrusion 302 at the front end of the substrate 301 and having a thickness greater than that of the substrate 301, and a rear protrusion 303 at the rear end of the substrate 301 and having a thickness greater than that of the substrate 301. One side of the substrate 301, together with the front protrusion 302 and the rear protrusion 303, forms a first groove 304. The other side of the substrate 301, together with the front protrusion 302 and the rear protrusion 303, forms a second groove 305. The power busbar 1 is accommodated in the first groove 304, and the ground return busbar 2 is accommodated in the second groove 305. The substrate 301 includes the recess 30, and the recess 30 divides the substrate 301 into two parts in the front-rear direction.

The mating interface 121 of the power busbar 1 and the mating interface 221 of the ground return busbar 2 are configured to electrically connect to the electrical component (not shown). The surfaces of the regions outside the mating interface 121 of the power busbar 1 and the regions outside the mating interface 221 of the ground return busbar 2 are insulated, thereby enhancing the electrical isolation between the power busbar 1 and the ground return busbar 2. The thermal conduit 4 extends substantially along the entire height of the power busbar 1 and the ground return busbar 2 in the vertical direction. The upper end of the thermal conduit 4 forms a liquid inlet port 41, and the lower end forms a liquid return port 42. Alternatively, the lower end of the thermal conduit 4 may form the liquid inlet port, and the upper end may form the liquid return port.

In some embodiments, the power busbar 1 and the ground return busbar 2 of the busbar assembly 100 share a single thermal conduit 4 located between them. The thickness W1 of the thermal conduit 4 is approximately equal to the sum of the thickness W2 of the substrate 301 of the isolator panel 3, the depth W3 of the first groove 304 of the power busbar 1, and the depth W4 of the second groove 305 of the ground return busbar 2. This configuration maximizes the cross-sectional size of the thermal conduit 4, reducing fluid flow resistance under the same pump conditions and effectively improving the heat dissipation efficiency of the thermal conduit 4 for the power busbar 1 and the ground return busbar 2. Additionally, the use of a single thermal conduit reduces manufacturing and assembly costs. Furthermore, the arrangement of the thermal conduit 4 passing through the isolator panel 3 between the power busbar 1 and the ground return busbar 2 prevents an increase in the overall width of the busbar assembly 100.

However, the disclosure is illustrative only, changes may be made in detail, especially in matter of shape, size, and arrangement of parts within the principles of the invention.

1. A busbar assembly comprising:
a power busbar having a mating interface configured to mate with an electrical component to supply power to the electrical component;
a ground return busbar electrically isolated from the power busbar, the ground return busbar having a mating interface configured to mate with the electrical component to provide a return path for the electrical component; and
a thermal conduit disposed between the power busbar and the ground return busbar; wherein
the thermal conduit extends along the power busbar and the ground return busbar and is configured to circulate liquid for dissipating heat from the power busbar and the ground return busbar.

2. The busbar assembly of claim 1, wherein the thermal conduit is electrically isolated from both the power busbar and the ground return busbar.

3. The busbar assembly of claim 1, wherein the thermal conduit has a thermally conductive insulating layer to electrically isolate the thermal conduit from the power busbar and the ground return busbar.

4. The busbar assembly of claim 1, further comprising an isolator panel disposed between the power busbar and the ground return busbar to electrically isolate the power busbar from the ground return busbar.

5. The busbar assembly of claim 4, wherein the isolator panel includes a recess to accommodate the thermal conduit and allows the thermal conduit to contact both the power busbar and the ground return busbar.

6. The busbar assembly of claim 5, wherein the power busbar has an inner surface and an outer surface opposite the inner surface, the inner surface faces the ground return busbar, the ground return busbar has an inner surface and an outer surface opposite the inner surface, the inner surface faces the power busbar, the inner surface of the power busbar has a first busbar channel, the inner surface of the ground return busbar has a second busbar channel, and the thermal conduit is accommodated in the first busbar channel and the second busbar channel.

7. The busbar assembly of claim 6, wherein the power busbar and the ground return busbar each have a rear portion and a front portion thinner than the rear portion, the outer side of the front portion of the power busbar forms the mating interface for providing a power path to the electrical component, the outer side of the front portion of the ground return busbar forms the mating interface for providing a return path to the electrical component, the inner surface of the rear portion of the power busbar has the first busbar channel, and the inner surface of the rear portion of the ground return busbar has the second busbar channel.

8. The busbar assembly of claim 7, wherein the isolator panel extends along the entire height of the power busbar and the ground return busbar, the isolator panel has a base plate, a front protrusion at a front end of the base plate and having a thickness greater than the base plate, and a rear protrusion at a rear end of the base plate and having a thickness greater than the base plate, one side of the base plate and the front and rear protrusions forms a first groove for accommodating the power busbar, the other side of the base plate and the front and rear protrusions forms a second groove for accommodating the ground return busbar, and the base plate includes the recess for accommodating the thermal conduit.

9. The busbar assembly of claim 7, wherein surfaces of the power busbar and the ground return busbar, except for the mating interfaces, are treated with an insulating layer.

10. The busbar assembly of claim 1, wherein the thermal conduit extends substantially along an entire height of the power busbar and the ground return busbar, and the thermal conduit includes a liquid inlet port at one end and a liquid outlet port at the other end.

11. A busbar assembly comprising:
a power busbar having a mating interface configured to mate with an electrical component to supply power to the electrical component; and
a ground return busbar electrically isolated from the power busbar, the ground return busbar having a mating interface configured to mate with the electrical component to provide a return path for the electrical component; and
a thermal conduit disposed between the power busbar and the ground return busbar to electrically isolate the power busbar from the ground return busbar.

12. The busbar assembly of claim 11, wherein the thermal conduit has an insulating layer to electrically isolate the thermal conduit from the power busbar and the ground return busbar.

13. The busbar assembly of claim 11, wherein the power busbar and the ground return busbar extend between an upper end and a lower end, and the thermal conduit extends substantially along an entire height of the power busbar and the ground return busbar.

14. The busbar assembly of claim 11, wherein the thermal conduit has a liquid inlet port at one end and a liquid outlet port at the other end.

15. The busbar assembly of claim 11, wherein the inner surface of the power busbar has a first busbar channel, the inner surface of the ground return busbar has a second busbar channel, and the thermal conduit is accommodated in the first busbar channel and the second busbar channel.

16. The busbar assembly of claim 15, further comprising an isolator panel disposed between the power busbar and the ground return busbar to electrically isolate the power busbar from the ground return busbar, and the isolator panel has a recess to accommodate the thermal conduit.

17. A busbar assembly comprising:
a first busbar; and
a second busbar disposed opposite the first busbar; and
a thermal conduit disposed between the first busbar and the second busbar to electrically isolate the first busbar from the second busbar.

18. The busbar assembly of claim 17, wherein the first busbar is a power busbar, the second busbar is a ground return busbar, and the thermal conduit is configured to circulate liquid for dissipating heat from the power busbar and the ground return busbar.

19. The busbar assembly of claim 18, wherein the power busbar has a mating interface configured to mate with an electrical component to provide a power path, the ground return busbar includes a mating interface configured to mate with the electrical component to provide a return path, and surfaces of the power busbar and the ground return busbar, except for the mating interfaces, are treated with an insulating layer.

20. The busbar assembly of claim 18, wherein an isolator panel is disposed between the power busbar and the ground return busbar, the power busbar and the ground return busbar are laminated with the isolator panel, the isolator panel includes a recess for accommodating the thermal conduit, and the thermal conduit contacts the power busbar and the ground return busbar.
